(19) United States
(12) Patent Application Publication
(10) Pub. No.: US 2009/0268417 A1
(43) Pub. Date: Oct. 29, 2009

(54) STORAGE APPARATUS AND PRINTED WIRING BOARD UNIT

(75) Inventor: Shigeru KAGAWA, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/500,858

(22) Filed: Jul. 10, 2009

Related U.S. Application Data
(63) Continuation of application No. PCT/JP2007/054971, filed on Mar. 13, 2007.

(51) Int. Cl. H05K 5/00; H05K 13/04; H05K 1/00

(52) U.S. Cl. 361/752; 29/592.1; 361/748; 361/679.33

(57) ABSTRACT

A flexible printed wiring board extends from a carriage block to an opening of an enclosure base. The flexible printed wiring board has lower and upper pieces. A connector on the lower surface of the lower piece is received in the opening. The upper piece has the lower surface opposed to the upper surface of the lower piece. A movable piece of the flexible printed wiring board has one end connected to the upper piece. The movable piece has the other end attached to the carriage block. A first aperture in the lower piece has a first diameter. A second aperture in the upper piece at a position corresponding to a position of the first aperture has a second diameter smaller than the first diameter. A screw is screwed into the enclosure base through the first aperture and the second aperture.

### CROSS-REFERENCE TO RELATED APPLICATION

This application is a continuing application, filed under 35 U.S.C. §111(a), of International Application PCT/JP2007/054971, filed on Mar. 13, 2007, the contents of which are incorporated herein by reference.

### FIELD

The embodiments discussed herein are related to a storage apparatus such as a hard disk drive, HDD, for example.

### BACKGROUND

A carriage is enclosed in the enclosure of a hard disk drive. A printed circuit board is fixed to the outside surface of the bottom plate of the enclosure. A connector is mounted on the printed circuit board. The connector protrudes into the inner space of the enclosure through the opening formed in the enclosure base. A flexible printed wiring board extending from the carriage is connected to the connector.

The flexible printed wiring board includes a movable piece having one end attached to the carriage. The flexible printed wiring board also includes a fixation piece extending from the other end of the movable piece. The fixation piece is attached to the bottom plate of the enclosure. The fixation piece is bent. The fixation piece defines a lower piece supporting the connector. The fixation piece further defines an upper piece overlaid on the upper surface of the lower piece. The movable piece is formed integral with the lower piece.
Publication 1: JP Patent Application Laid-open No. 9-274837
Publication 2: JP Patent Application Laid-open No. 9-128911

A gap is formed between the connector and the edge of the opening. As a result, when the connector shifts from a predetermined position inside the opening, the lower piece shifts from a predetermined position. Since the movable piece is formed integral with the lower piece, the tension of the movable piece deviates from a designed value in response to such a shift in the position of the lower piece. Such a variation in the tension hinders the carriage from swinging as designed. A head slider thus cannot be positioned with a higher accuracy. In particular, since the size of a flexible printed wiring board is ever reduced because of a recent reduction in the size of a hard disk drive, it is expected to set the tension of the movable piece as designed.

### SUMMARY

According to a first aspect of the present invention, there is provided a storage apparatus comprising: an enclosure base; an opening formed in the enclosure base; a carriage block pivotally supported on a pivotal shaft standing on the enclosure base; a flexible printed wiring board extending from the carriage block to the opening; a lower piece defined in the flexible printed wiring board, the lower piece having the lower surface overlaid on the enclosure base; a connector attached to the lower surface of the lower piece, the connector received in the opening of the enclosure base; an upper piece defined in the flexible printed wiring board, the upper piece connected to the lower piece, the upper piece having the lower surface opposed to an upper surface of the lower piece; a movable piece defined in the flexible printed wiring board, the movable piece having one end connected to the upper piece, the movable piece having the other end attached to the carriage block; a first aperture or apertures formed in the lower piece, the first aperture or apertures having a first diameter; a second aperture or apertures formed in the upper piece at a position or positions corresponding to a position or positions of the first aperture or apertures, the second aperture or apertures having a second diameter smaller than the first diameter; and a screw screwed into the enclosure base through the first aperture and the second aperture.

According to a second aspect of the present invention, there is provided a method of making a storage apparatus, comprising: overlaying a first piece of a flexible printed wiring board on the enclosure of a storage apparatus while a connector is inserted into an opening defined in the enclosure, thereby positioning a screw bore inside a first aperture having a first diameter, the screw bore defined in the enclosure, the first aperture defined in the first piece; and inserting a screw into a second aperture overlaid on the first aperture, thereby aligning a second piece with the first piece, the second aperture defined in the second piece integral to the first piece in the flexible printed wiring board, the second piece overlaid on the first piece, the screw being screwed into the screw bore while the second piece is aligned with the first piece, the second aperture having a second diameter smaller than the first diameter.

According to a third aspect of the present invention, there is provided a printed wiring board unit comprising: first and second pieces defined in a single thin plate, the first and second pieces connected to each other via a connecting piece defined in the thin plate; a connector attached to the surface of the first piece; a movable piece connected to the second piece; a first aperture or apertures formed in the first piece, the first aperture or apertures having a first diameter; and a second aperture or apertures formed in the second piece, the second aperture or apertures having a second diameter smaller than the first diameter, the center of the second aperture or the centers of the second apertures and the center of the first aperture or the centers of the first apertures establishing a bilateral symmetry relative to the symmetric axis crossing the connecting piece between the first piece and the second piece.

The object and advantages of the embodiments will be realized and attained by means of the elements and combinations particularly pointed out in the appended claims. It is to be understood that both the foregoing general description and the following detailed description are exemplary and explanatory and are not restrictive of the embodiments, as claimed.

### BRIEF DESCRIPTION OF THE DRAWINGS

FIG. 1 is a perspective view schematically depicting a hard disk drive, HDD, as a specific example of a storage apparatus according to the present invention;

FIG. 2 is a plan view schematically depicting the inner structure of the hard disk drive;

FIG. 3 is an enlarged partial perspective view schematically depicting a printed circuit board unit according to a specific example of the present invention;

FIG. 4 is a partial sectional view taken along the line 4-4 in FIG. 3;

FIG. 5 is a partial sectional view taken along the line 5-5 in FIG. 3;

FIG. 6 is a plan view schematically depicting the farside of the hard disk drive; and

FIG. 7 is a plan view schematically depicting the printed circuit board unit according to the specific example of the present invention.

### DESCRIPTION OF EMBODIMENTS

Description will be made below on embodiments of the present invention with reference to the attached drawings.

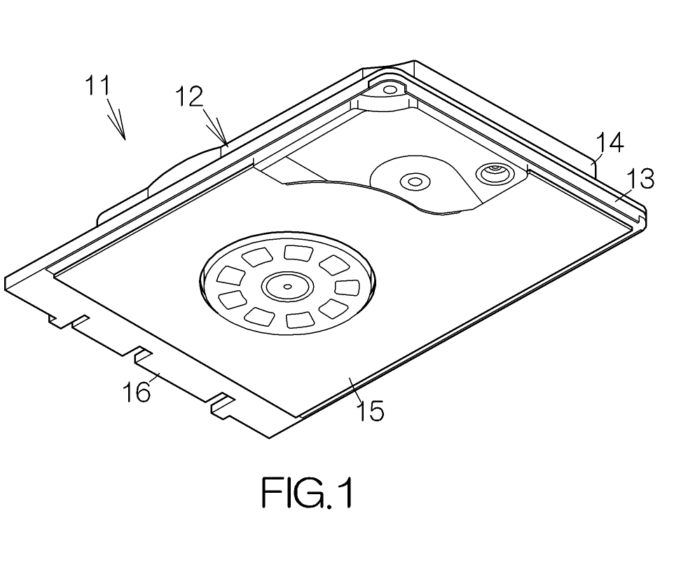

FIG. 1 schematically depicts a hard disk drive, HDD, 11 as an example of a storage medium drive or a storage apparatus according to an embodiment. The hard disk drive 11 includes a box-shaped enclosure 12. The box-shaped enclosure 12 includes a box-shaped enclosure base 13. The box-shaped enclosure base 13 defines an inner space in the form of a flat parallelepiped, for example. An enclosure cover 14 is coupled to the box-shaped enclosure base 13. The enclosure cover 14 closes the opening of the box-shaped enclosure base 13. Pressing process may be employed to form the box-shaped enclosure base 13 and the enclosure cover 14 out of a single plate material, respectively, for example. A printed circuit board 15 is fixed to the farside of the bottom plate of the box-shaped enclosure base 13. A connector 16 is coupled to the printed circuit board 15.

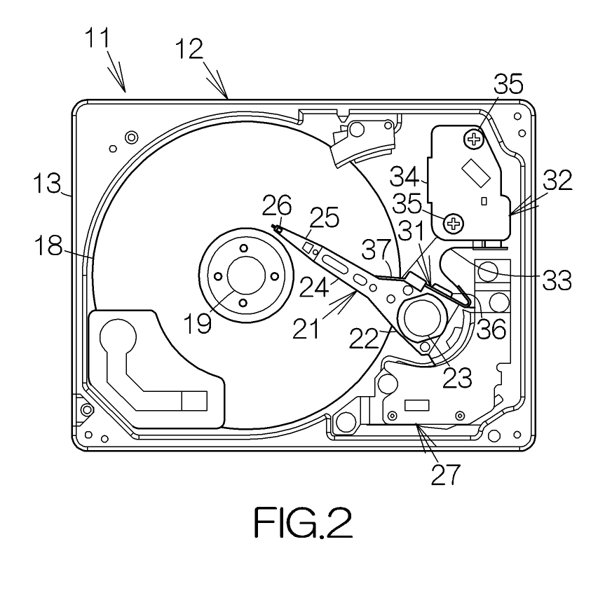

As depicted in FIG. 2, at least one magnetic recording disk 18 as a magnetic recording medium is placed in the inner space of the box-shaped enclosure base 13. The magnetic recording disk or disks 18 is mounted on the driving or spindle shaft of a spindle motor 19. The spindle motor 19 drives the magnetic recording disk or disks 18 at a higher revolution speed such as 5,400 rpm, 7,200 rpm, 10,000 rpm, 15,000 rpm, or the like. The individual magnetic recording disk 18 has the diameter of 1.8 inches, for example.

A carriage 21 is also enclosed in the box-shaped enclosure base 13. The carriage 21 includes a carriage block 22. The carriage block 22 is pivotally coupled on a vertical pivotal shaft 23. The vertical pivotal shaft 23 stands upright from the bottom plate of the box-shaped enclosure base 13. Screws, not depicted, are utilized to fix the vertical pivotal shaft 23 to the bottom plate of the box-shaped enclosure base 13, for example. Carriage arms 24 are defined in the carriage block 22. The carriage arms 24 extend in a horizontal direction from the vertical pivotal shaft 23. The carriage block 22 may be made of aluminum (Al), for example. Extrusion process may be employed to form the carriage block 22, for example.

A head suspension 25 is attached to the front or tip end of the individual carriage arm 24. The head suspension 25 extends forward from the carriage arm 24. A flexure is attached to the head suspension 25. A so-called gimbal is defined in the flexure. The gimbal spring allows a flying head slider 26 to change its attitude relative to the head suspension 25. A head element, namely an electromagnetic transducer, not depicted, is mounted on the flying head slider 26.

When the magnetic recording disk 18 rotates, the flying head slider 26 is allowed to receive airflow generated along the rotating magnetic recording disk 18. The airflow serves to generate a positive pressure or lift as well as a negative pressure on the flying head slider 26. The lift is balanced with the urging force of the head suspension 25 and the negative pressure so that the flying head slider 26 keeps flying above the surface of the magnetic recording disk 18 at a higher stability during the rotation of the magnetic recording disk 18.

When the carriage 21 swings around the vertical pivotal shaft 23 during the flight of the flying head slider 26, the flying head slider 26 is allowed to move in the radial direction of the magnetic recording disk 18. The electromagnetic transducer on the flying head slider 26 is thus allowed to cross the data zone defined between the innermost and outermost recording tracks. The electromagnetic transducer on the flying head slider 26 is positioned on a target recording track on the magnetic recording disk 18.

A power source such as a voice coil motor, VCM, 27 is coupled to the carriage block 22. The voice coil motor 27 serves to drive the carriage block 22 around the vertical pivotal shaft 23. The rotation of the carriage block 22 allows the carriage arms 24 and the head suspensions 25 to swing.

As is apparent from FIG. 2, a flexible printed circuit board unit 31 is located on the carriage block 22. The flexible printed circuit board unit 31 includes a flexible printed wiring board 32. A movable piece 33 is defined in the flexible printed wiring board 32. One end of the movable piece 33 is attached to the side surface of the carriage block 22. The movable piece 33 extends in a curve. A fixation plate 34 extends continuously from the movable piece 33. The fixation piece 34 is attached to the bottom plate of the box-shaped enclosure base 13. A pair of screws 35 is utilized to fix the fixation piece 34 to the box-shaped enclosure base 13, for example. The screws 35 are screwed into the bottom plate of the box-shaped enclosure base 13.

A head IC (integrated circuit) 36 is mounted on the surface of the movable piece 33. The head IC 36 is connected to the read head element and the write head element of the electromagnetic transducer. Flexible printed wiring boards 37 are utilized to establish such connections. The flexible printed wiring boards 37 are continuous from the individual flexures, respectively. The flexible printed wiring boards 37 are connected to the flexible printed circuit board unit 31. The head IC 36 is designed to supply the read head element of the electromagnetic transducer with a sensing current when magnetic bit data is to be read. The head IC 36 is also designed to supply the write head element of the electromagnetic transducer with a writing current when magnetic bit data is to be written. The current value of the sensing current is set at a specific value.

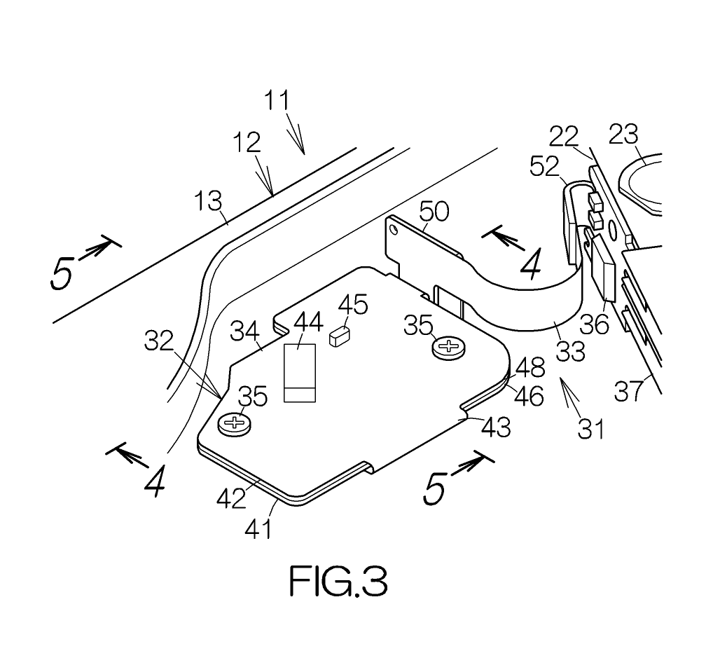

As depicted in FIG. 3, the fixation piece 34 includes a lower piece 41 serving as a first piece, and an upper piece 42 serving as a second piece. The lower piece 41 defines the downward or lower surface overlaid on the upper surface of the box-shaped enclosure base 13. The upper piece 42 is overlaid on the upward or upper surface of the lower piece 41. The movable piece 33 is connected to the upper piece 42. A connecting piece 43 connects the lower piece 41 to the upper piece 42. The movable piece 33, the lower piece 41, the upper piece 42 and the connecting piece 43 are integrally formed together. A shock sensor 44 and a thermistor 45 are mounted on the upper surface of the upper piece 42. The shock sensor 44 detects impact acting on the hard disk drive 11. The thermistor 45 detects the temperature inside the box-shaped enclosure 12.

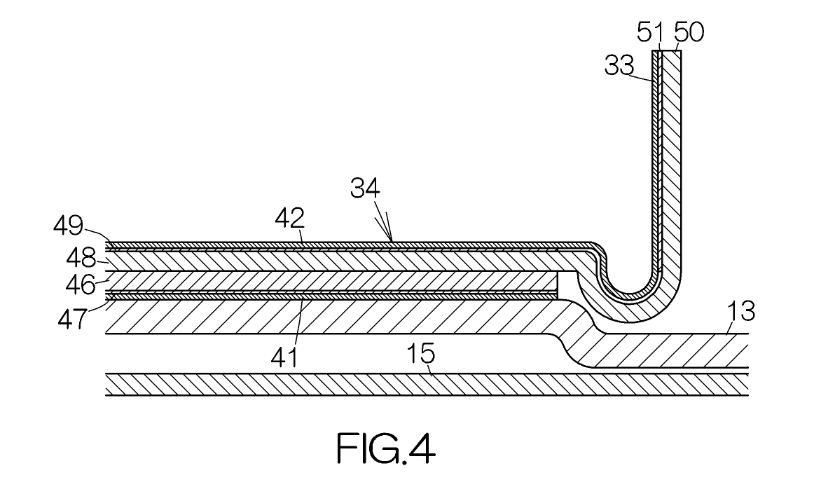

Referring also to FIG. 4, a first support plate 46 is bonded to the upward or upper surface of the lower piece 41. An adhesive layer 47 is utilized to bond the first support plate 46, for example. A second support plate 48 is bonded to the downward or lower surface of the upper piece 42. An adhesive layer 49 is utilized to bond the second support plate 48, for example. The downward or lower surface of the second support plate 48 is overlaid on the upward or upper surface of the first support plate 46. The first support plate 46 and the second support plate 48 are made of sheet metal, for example. No adhesive is disposed between the first support plate 46 and the second support plate 48. Accordingly, the first and second support plates 46, 48, namely the lower and upper pieces 41, 42, are allowed to move relative to each other even when the first and second support plates 46, 48 are brought in contact with each other.

The upper piece 42 is continuous from the aforementioned movable piece 33. The movable piece 33 is partially bonded to a support piece 50. The support piece 50 is formed integral with the second support plate 48. An adhesive layer 51 may be utilized to bond the movable piece 33. The support piece 50 bends from the second support plate 48 to stand upright from the surface of the bottom plate of the box-shaped enclosure base 13 outside the second support plate 48. One end of the movable piece 33 is supported on a fixation plate 52 fixed to the side surface of the carriage block 22. The fixation plate 52 may be made of a metal plate. The movable piece 33 in this manner extends in a curve between the carriage block 22 and the support piece 50.

Here, the flexible printed wiring board 32 includes an insulating thin plate, an electrically-conductive layer overlaid on the surface of the insulating thin plate, and a protection film overlaid on the surface of the electrically-conductive layer. The electrically-conductive layer forms a wiring pattern or patterns extending on the flexible printed wiring board 32. The electrically-conductive layer may be made of an electrically-conductive material such as copper, for example. The insulating thin plate and the protection film may be made of a resin material such as polyimide resin, for example. An adhesive layer may be interposed between the insulating thin plate and the electrically-conductive layer and between the electrically-conductive layer and the protection film.

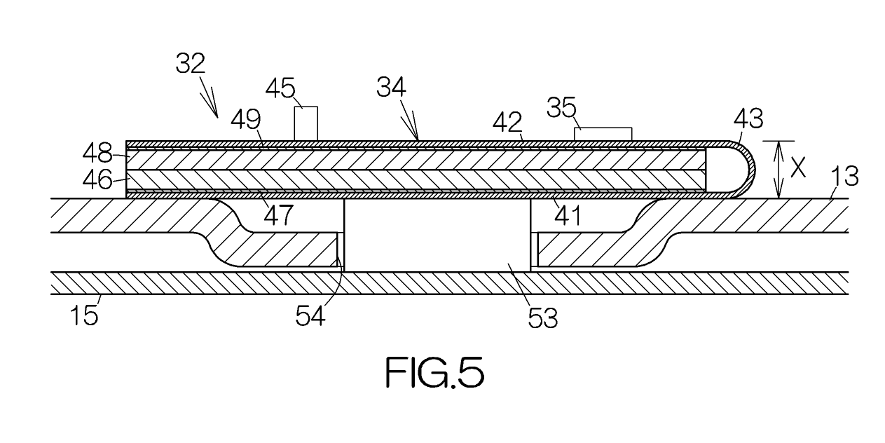

As depicted in FIG. 5, a connector 53 is attached to the downward or lower surface of the lower piece 41. The connector 53 is received in a rectangular opening 54 formed in the bottom plate of the box-shaped enclosure base 13. A predetermined gap is defined between the connector 53 and the edge of the rectangular opening 54, namely the wall surface defining the rectangular opening 54. The connector 53 protrudes into the outer space through the bottom plate of the box-shaped enclosure base 13. The connector 53 is inserted into a receptacle or receiving connector on the aforementioned printed circuit board 15. In this manner, the connector 53 is coupled to the printed circuit board 15. Electric current is supplied to the head IC 36 from the printed circuit board 15 through the flexible printed wiring board 32.

The connecting piece 43 may extend from the outer periphery of the first support plate 46 to the outer periphery of the second support plate 48 over a predetermined length. Here, the length of the connecting piece 43 may be set equal to or longer than the length of the arc of a semicircle having a radius equal to half a distance X between the lower surface of the lower piece 41 and the upper surface of the upper piece 42. When the length of the connecting piece 43 is set in this manner, the connecting piece 43 relatively easily deforms. Deformation of the connecting piece 43 allows the relative movement between the lower piece 41 and the upper piece 42 in a method of attaching the flexible printed wiring board 32.

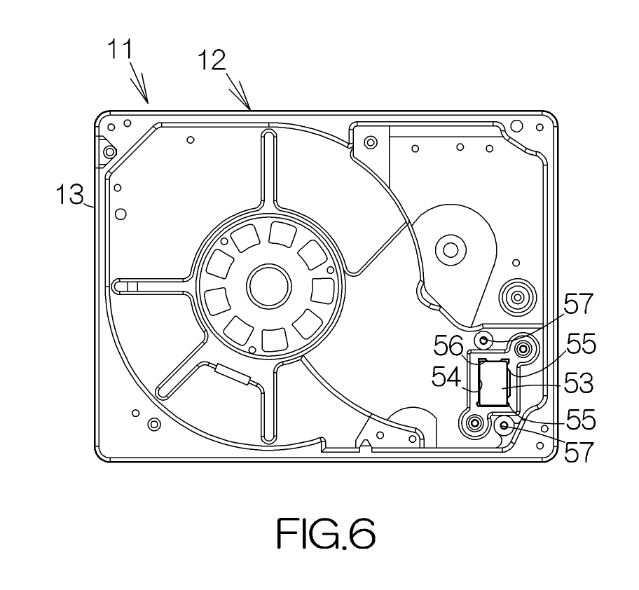

As depicted in FIG. 6, a pair of protrusions 55, 55 is formed on a flat wall surface corresponding to a long side of the rectangular opening 54 formed in the box-shaped enclosure base 13. A projection 56 is formed on a flat wall surface corresponding to a short side, perpendicular to the long side, of the rectangular opening 54, for example. The side surfaces of the connector 53 are received on the protrusions 55 and the projection 56. When the connector 53 is received in the rectangular opening 54, the side surfaces of the connector 53 are urged against the protrusions 55 and the projection 56, as described later in detail. The connector 53 is in this manner positioned at a predetermined location. A pair of screw bores 57 is formed in the bottom plate of the enclosure base 13 off the rectangular opening 54. The aforementioned screws 35 are screwed into the screw bores 57.

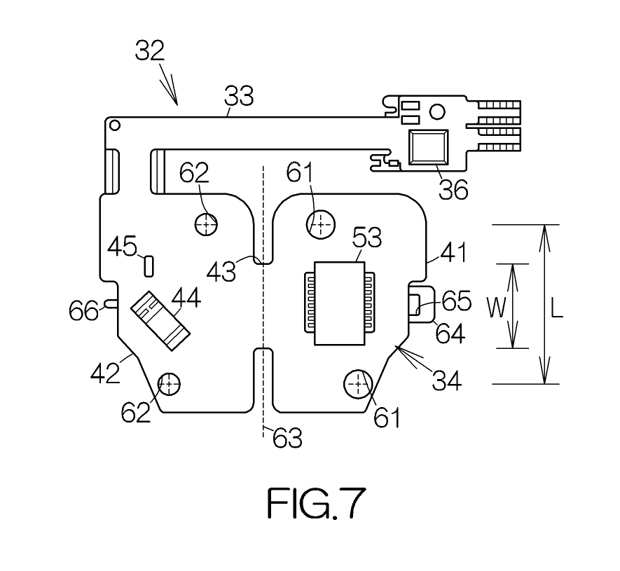

Next, assume that the flexible printed circuit board unit 31 is to be attached to the box-shaped enclosure base 13. Prior to the attachment of the flexible printed circuit board unit 31, the flexible printed wiring board 32 is prepared as depicted in FIG. 7. The flexible printed wiring board 32 is made out of a single thin plate. The head IC 36 has already been mounted on one end of the movable piece 33. The connector 53 has already been mounted on the surface of the lower piece 41. The shock sensor 44 and the thermistor 45 have already been mounted on the surface of the upper piece 42.

A pair of first apertures 61, 61 is formed in the lower piece 41. The first apertures 61 have a first diameter. The first diameter is set at 2.1 mm approximately, for example. Likewise, a pair of second apertures 62, 62 is formed in the upper piece 42. The second apertures 62 have a second diameter smaller than the first diameter. The second diameter is set at 1.5 mm approximately, for example. The thread diameter of the screws 35 is set at M1.4. The individual screw 35 is received in the corresponding first aperture 61 and the corresponding second aperture 62. The dimensions of the first apertures 61 and the second apertures 62 may be determined depending on the relationship with the thread diameter of the screws 35. Here, the dimensions of the first apertures 61 and the second apertures 62 are set in view of a deviation angle of two degrees for the attitude of the connector 53. The difference between the first and second diameters depends on the rotation in the attitude of the connector 53 around an axis intersecting the lower piece 41 at right angles.

The centers of the first apertures 61 and the centers of the second apertures 62 establish a bilateral symmetry relative to a symmetric axis 63 crossing the connecting piece 43 within a space between the lower piece 41 and the upper piece 42. The width W of the connecting piece 43, corresponding to a dimension of the connecting piece 43 in the direction of the symmetric axis 63 within a plane including the surfaces of the first and second pieces 41, 42, is set smaller than the distance L between the centers of the first apertures 61, 61 as well as between the centers of the second apertures 62, 62. Here, the width W is set at half the length L approximately, for example. When the width W of the connecting piece 43 is set smaller than the distance L between the first apertures 61 as well as between the second apertures 62, the connecting piece 32 is allowed to deform in a relatively easier manner.

An engaging piece 64 is defined in the lower piece 41. The engaging piece 64 protrudes from the contour of the lower piece 41. An opening 65 is defined between the engaging piece 64 and the outer periphery of the lower piece 41. A protrusion 66 is defined in the upper piece 42 at a position symmetric to the position of the opening 65 with respect to the aforementioned symmetric axis 63. The protrusion 66 protrudes from the contour of the upper piece 42. Openings of the first diameter are formed in the first support plate 46, bonded to the backside of the lower piece 41, at positions reflecting the positions of the first apertures 61, respectively. Likewise, openings of the second diameter are formed in the second support plate 48, bonded to the backside of the upper piece 42, at positions reflecting the positions of the second apertures 62, respectively.

Prior to the attachment to the box-shaped enclosure base 13, the single thin plate is folded in half at the symmetric axis 63 so as to overlay the lower piece 41 onto the upper piece 42. The first support plate 46 is overlaid on the second support plate 48. In this case, the protrusion 66 of the upper piece 42 is received in the opening 65 inside the engaging piece 64. The protrusion 66 is engaged with the engaging piece 64. The elastic force of the engaging piece 64 and the protrusion 66 allows the lower piece 41 and the upper piece 42 to be temporarily held together. The lower piece 41 can be kept overlaid on the upper piece 42. Deformation in the connecting piece 43 serves to accept the relative movement between the lower piece 41 and the upper piece 42. The fixation piece 52, supporting one end of the movable piece 33, is fixed on the side surface of the carriage block 22. Screws may be utilized for such fixation, for example. The head suspension 25 has already been attached to the tip end of the individual carriage arm 24.

The carriage 21 is mounted on the vertical pivotal shaft 23 on the box-shaped enclosure base 13. The flexible printed circuit board unit 31 is placed in the inner space of the box-shaped enclosure base 13. The connector 53 is inserted in the rectangular opening 54 of the box-shaped enclosure base 13. The side surfaces of the connector 53 are urged against the protrusions 55 and the projection 56. The lower piece 41 is overlaid on the bottom plate of the box-shaped enclosure base 13. The screw bores 57 of the bottom plate of the box-shaped enclosure base 13 are positioned at specific locations inside the first apertures 61 of the lower piece 41, respectively. The second apertures 62 of the upper piece 42 are overlaid on the first apertures 61, respectively. The screws 35 are continuously inserted through the first and second apertures 61, 62. While the upper piece 42 is positioned relative to the lower piece 41, the screws 35 are screwed into the screw bores 57. The lower piece 41 and the upper piece 42 are in this manner fixed to the bottom plate of the box-shaped enclosure base 13.

The hard disk drive 11 allows the screws 35 to enter the aligned first and second apertures 61, 62 for the attachment of the flexible printed circuit board unit 31. The diameter of the first apertures 61 is set larger than the thread diameter of the screws 35. The width W of the connecting piece 43 is set relatively small. A relative movement can thus be allowed between the lower piece 41 and the upper piece 42 when the screws 35 are screwed. Since the predetermined gap is established between the connector 53 and the wall surfaces defining the rectangular opening 54, the connector 53 is assumably located at a position shifted from a predetermined position inside the rectangular opening 54. The movement of the lower piece 41 serves to absorb such a shift of the connector 53 inside the rectangular opening 54.

The diameter of the second apertures 62 is approximately equal to the thread diameter of the screws 35. The screws 35 and the second apertures 62 thus serve to accurately position the upper piece 42 relative to the screw bores 57 of the box-shaped enclosure base 13 irrespective of the relative movement of the lower piece 41. The tension of the movable piece 33 connected to the upper piece 42 can be set as designed. The movable piece 33 is reliably prevented from being tightened or loosened. The carriage block 22 coupled to the movable piece 33 is allowed to swing as designed.

The flexible printed circuit board unit 31 may include the first apertures 61 of the lower piece 41 and the second apertures 62 of the upper piece 42 both formed as notches. In this case, the individual notch may be formed in the shape of an arc of three quadrants or larger.

All examples and conditional language recited herein are intended for pedagogical purposes to aid the reader in understanding the invention and the concept contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A storage apparatus comprising:
an enclosure base;
an opening formed in the enclosure base;
a carriage block pivotally supported on a pivotal shaft standing on the enclosure base;
a flexible printed wiring board extending from the carriage block to the opening;
a lower piece defined in the flexible printed wiring board, the lower piece having a lower surface overlaid on the enclosure base;
a connector attached to the lower surface of the lower piece, the connector received in the opening of the enclosure base;
an upper piece defined in the flexible printed wiring board, the upper piece connected to the lower piece, the upper piece having a lower surface opposed to an upper surface of the lower piece;
a movable piece defined in the flexible printed wiring board, the movable piece having one end connected to the upper piece, the movable piece having an other end attached to the carriage block;
a first aperture or apertures formed in the lower piece, the first aperture or apertures having a first diameter;
a second aperture or apertures formed in the upper piece at a position or positions corresponding to a position or positions of the first aperture or apertures, the second aperture or apertures having a second diameter smaller than the first diameter; and
a screw screwed into the enclosure base through the first aperture and the second aperture.

2. The storage apparatus according to claim 1, further comprising a connecting piece defined in the flexible printed wiring board between the lower piece and the upper piece, the connecting piece having a width smaller than a distance between the first apertures.

3. The storage apparatus according to claim 1, further comprising a connecting piece defined in the flexible printed wiring board between the lower piece and the upper piece, the connecting piece extending over a length equal to or longer than a length of an arc of a semicircle having a radius equal to half a distance between the lower surface of the lower piece and the upper surface of the upper piece.

4. A method of making a storage apparatus, comprising:
overlaying a first piece of a flexible printed wiring board on an enclosure of a storage apparatus while a connector is inserted into an opening defined in the enclosure, thereby positioning a screw bore inside a first aperture having a first diameter, the screw bore defined in the enclosure, the first aperture defined in the first piece; and
inserting a screw into a second aperture overlaid on the first aperture, thereby aligning a second piece with the first piece, the second aperture defined in the second piece integral to the first piece in the flexible printed wiring board, the second piece overlaid on the first piece, the screw being screwed into the screw bore while the second piece is aligned with the first piece, the second aperture having a second diameter smaller than the first diameter.

5. A printed wiring board unit comprising:
first and second pieces defined in a single thin plate, the first and second pieces connected to each other via a connecting piece defined in the thin plate;
a connector attached to a surface of the first piece;
a movable piece connected to the second piece;
a first aperture or apertures formed in the first piece, the first aperture or apertures having a first diameter; and
a second aperture or apertures formed in the second piece, the second aperture or apertures having a second diameter smaller than the first diameter, a center of the second aperture or centers of the second apertures and a center of the first aperture or centers of the first apertures establishing a bilateral symmetry relative to a symmetric axis crossing the connecting piece between the first piece and the second piece.

6. The printed wiring board unit according to claim 5, wherein the connecting piece has a width smaller than a distance between the first apertures.

7. The printed wiring board unit according to claim 5, wherein the connecting piece extends over a length equal to or longer than a length of an arc of a semicircle having a radius equal to half a distance between a front surface of the first piece and a front surface of the second piece when a back surface of the second piece is opposed to a back surface of the first piece.
